(19) United States
(12) Patent Application Publication
(10) Pub. No.: US 2025/0218903 A1
(43) Pub. Date: Jul. 3, 2025

(54) VIA REVEAL PROCESSING AND STRUCTURES

(71) Applicant: ADEIA SEMICONDUCTOR BONDING TECHNOLOGIES INC., San Jose, CA (US)

(72) Inventors: Cyprian Emeka Uzoh, San Jose, CA (US); Gaius Gillman Fountain, JR., Youngsville, NC (US)

(21) Appl. No.: 18/745,862

(22) Filed: Jun. 17, 2024

Related U.S. Application Data
(60) Provisional application No. 63/615,716, filed on Dec. 28, 2023.

(51) Int. Cl. H01L 23/48; H01L 21/768; H01L 23/00

(52) U.S. Cl. CPC H01L 23/481; H01L 21/76816; H01L 21/76831; H01L 21/7684; H01L 24/05; H01L 2224/05568; H01L 2924/351

(57) ABSTRACT

Disclosed are methods of microelectronic processing to reveal conductive vias that are at least partially embedded in a bulk semiconductor, and resulting structures. A method of forming a microelectronic structure includes revealing the plurality of conductive vias from a back surface of the bulk semiconductor and forming a protective cap on each of the conductive vias on the back surface of the bulk semiconductor. The protective caps can be patterned or disposed selectively onto the conductive vias. The protective caps can cover the conductive vias or also cover a portion of the bulk semiconductor surrounding the conductive vias. The back surface of the bulk semiconductor is etched to form protruding conductive vias, which can be surrounded by sleeves of the bulk semiconductor. A dielectric layer is deposited over the back surface and planarized to reveal the plurality of conductive vias from the back surface.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### FIELD

The field relates to structures with vias extending within substrates and methods for revealing the vias embedded in a substrate.

### BACKGROUND

Microelectronic elements, and more particularly semiconductor elements, such as integrated device dies or chips, may be mounted or stacked on other elements. For example, a semiconductor element can be mounted to a carrier, such as a package substrate, an interposer, a reconstituted wafer or element, or other semiconductor element. As another example, a semiconductor element can be stacked on top of another semiconductor element, e.g., a first integrated device die can be stacked on a second integrated device die. In some arrangements, a through-substrate via (TSV) can extend vertically through a thickness of the semiconductor element to transfer electrical signals through the semiconductor element, e.g., from a first surface of the semiconductor element to a second opposing surface of the semiconductor element. In some arrangements, the TSVs extend only partially through an original thickness of the semiconductor element; then a backside of the semiconductor element can be processed or thinned to expose the TSV from the backside. There is a continuing need for improved methods of processing backsides of semiconductor elements to expose TSVs.

### BRIEF DESCRIPTION OF THE DRAWINGS

The detailed description is set forth with reference to the accompanying figures, which are meant to illustrate and not to limit the invention. The use of the same reference numbers in different figures indicates similar or identical items. Additionally, the use of reference numerals that increment by 100 with each figure (e.g., 310 in FIG. 3B, 410 in FIG. 4B, etc.) also indicate similar or identical items, unless otherwise specified.

For this discussion, the devices and systems illustrated in the figures are shown as having a multiplicity of components. Various implementations of devices and/or systems, as described herein, may include fewer components and remain within the scope of the disclosure. Alternatively, other implementations of devices and/or systems may include additional components, or various combinations of the described components, and remain within the scope of the disclosure.

FIG. 1A is a schematic side sectional view of two elements before being hybrid bonded, according to an embodiment.

FIG. 1B is a schematic side sectional view of the two elements of FIG. 1A after being hybrid bonded, according to an embodiment.

FIGS. 2A-2F are a series of schematic side sectional views that show a method by which a backside of a microelectronic structure can be thinned to expose embedded vias and prepared for hybrid bonding.

FIGS. 3A-3M are a series of schematic side sectional views that show a method by which a backside of a microelectronic structure can be thinned to expose embedded vias, using selective backside caps, prepared for hybrid bonding, and then bonded to a second element to form a bonded structure and singulated, according to an embodiment.

FIGS. 4A-4F are a series of schematic side sectional views that show a method by which a backside of a microelectronic structure can be thinned to expose embedded vias, using selective backside caps that extend laterally, prepared for hybrid bonding, and then bonded to a second element to form a bonded structure, according to an embodiment.

FIGS. 5A-5F are a series of schematic side sectional views that show a method by which a backside of a microelectronic structure can be thinned to expose embedded vias, using selective backside caps that are at least partially incorporated into the structure, and prepared for hybrid bonding, according to an embodiment.

FIGS. 6A-6E are a series of schematic side sectional views that show a method by which a backside of a microelectronic structure can be thinned to expose embedded vias, using selective backside caps, and prepared for hybrid bonding, according to an embodiment.

FIGS. 7A-7F are a series of schematic side sectional views that show a method by which a backside of a microelectronic structure can be thinned to expose embedded vias, using patterned backside caps, and prepared for hybrid bonding, according to an embodiment.

### DETAILED DESCRIPTION OF PREFERRED EMBODIMENTS

Embodiments described herein facilitate hybrid bonding substrates having vias embedded in substrates, such as but not limited to through substrate vias (TSVs). Novel techniques are taught for thinning and processing the back sides of substrates to reveal vias from the substrate, such as at the substrate backside, that provide advantages in preparation for hybrid bonding. In some embodiments, vias of varying depths are embedded in the substrate, such as “via first” or “via middle” TSVs that extend from a front side of the substrate only partially through an original thickness of the substrate. The back side of the substrate is thinned (e.g., by grinding and/or polishing) to reveal all the vias. After cleaning the back surface to remove contaminants including smeared metal from the vias, caps can be disposed onto the back side of the revealed vias. The caps can protect the vias during subsequent processing steps when the vias are vulnerable to damage.

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive or non-conductive filler materials, can be applied to one or both elements and cured to form the physical (rather than chemical or covalent) connection between elements. Some organic adhesives may lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials without organic adhesives. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements at temperatures higher than the initial assembly temperature.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and can be subject to reversal by reheating. Furthermore, an intermetallic layer that often results from such fusible metal alloys may be brittle, which poses a reliability concern for the bonded elements. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

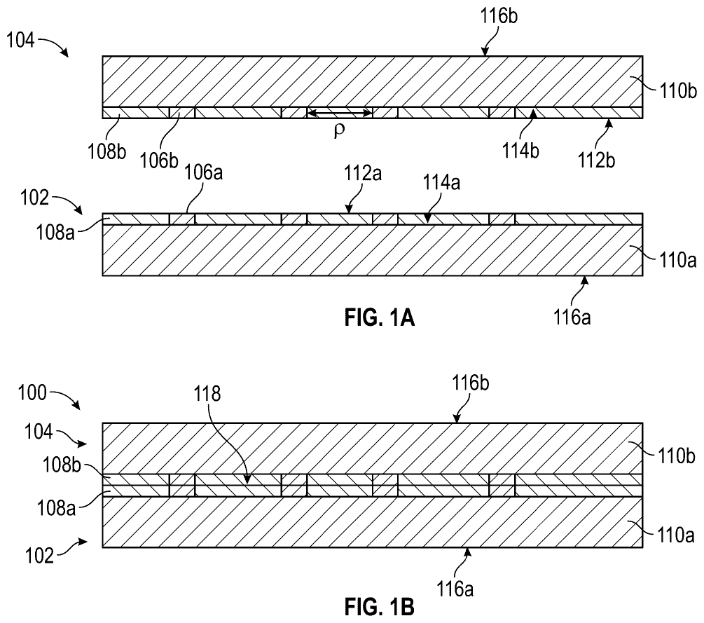

FIGS. 1A and 1B schematically illustrate cross-sectional side views of first and second elements 102, 104 prior to and after, respectively, a process for forming a directly bonded structure, and more particularly a hybrid bonded structure, according to some embodiments. In FIG. 1B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, the base substrate portions 110a, 110b may not include active circuitry, but may instead comprise dummy substrates, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C. For example, the CTE difference between the base substrate portions 110a and 110b can be in a range of 2 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO₃) or lithium niobate (LiNbO₃), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises a packaging material, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), die-to-wafer (D2W), wafer-to-panel (W2P), or die-to-panel (D2P) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed or protruded relative to the field regions of the bonding layers 108a, 108b, as desired for particular applications.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen and/or fluorine. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. Nos. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding field regions, such that a total gap between opposing contacts after dielectric bonding and prior to anneal is less than 60 nm, less than 15 nm, or less than 10 nm, depending on the width, the volume of conductive material in or below the conductive features 106a, 106b and the annealing temperature. Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 106a, 106b can comprise discrete pads, contacts, electrodes, vias or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 1A prior to direct bonding, portions of the respective conductive features 106a and 106b can be recessed below the non-conductive bonding surfaces 112a and 112b, for example, recessed by less than 60 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the feature, and so can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBIR, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

Embodiments taught herein involve vias, such as backside-revealed TSVs, for hybrid bonding. Vias can be formed by many different methods, including via-first, via-middle, or via-last techniques. In via-first or via-middle processes, relatively deep (e.g., multiple microns in depth) blind openings are opened from the front side of the substrate, or from the front side of BEOL layers thereover, such as by reactive ion etching (RIE) or laser drilling. The substrate can be a bulk semiconductor material (e.g., silicon, III-V materials, optical semiconductor materials, etc.) with active devices, but in other embodiments the substrate can be glass or ceramic, particularly for passive elements like interposers or carrier substrates. For active element embodiments, the front side of the substrate typically includes devices, such as transistors, and BEOL metallization layers, which can be formed before or after defining the TSV structures. For example, in via middle process, transistors are formed via high temperature front end process, after which, blind TSVs are formed, followed by multi layers of metallization or BEOL layers. The blind openings are filled with conductive material, typically predominantly copper due to its high conductivity. At this stage the vias can be considered buried, blind, or embedded TSVs which do not actually extend all the way to the back side of the substrate, as the substrate has not yet been thinned to its final thickness. Subsequently the substrate (e.g., bulk semiconductor material) is thinned from the back side to reveal the back sides of the conductive material, and effectively form the TSVs extending from the front side of the substrate to the back side of the thinned substrate.

One problem with via-first or via-middle TSVs is that, due to the great depth that the openings are etched into the bulk substrate material, the openings tend not to have identical depths, and there can be a great deal of variation in pre-reveal TSV depth across the substrate. For example, TSV formed near the center of the wafer may have different depths than those near the edge of the wafer. This variable-depth issue can be exacerbated when the vias have different widths, such as different widths for power or ground as compared to signal vias. The consequent variation in height of the TSVs complicates the process of thinning the substrate from the backside to a uniform thickness that reveals even the shallower TSVs. One process for thinning the substrate from the backside involves thinning the back side of the substrate (e.g., grinding and/or polishing) without revealing any TSVs, or only exposing the deepest of the TSVs; then exposing the back side of the substrate to an etchant that preferentially etches the substrate material compared to the TSVs, for enough time to reveal even the shallower TSVs; then polishing the backside of the substrate with protruding TSVs with non-uniform protruding heights. Such processes can cause problems, such as wearing away of some of the via liner layer(s) that protect the conductive TSVs (e.g., during the etching of the substrate) by prolonged exposure to imperfectly selective etches, TSV breakage or cracking due to high stress (shear and bending load) on the TSV structure during the polishing, and breakage of some of the taller or thinner TSVs (e.g., during the polishing of the protruding TSVs). Embodiments taught herein can alleviate some of the problems introduced during back side reveal and subsequent processing by the potential for disposing protective caps onto the revealed ends of vias during specific processing steps when the vias are vulnerable to damage.

In some embodiments, the cap is a selective cap that is preferentially deposited onto the conductive material of a via, as compared to other exposed portions of the substrate. In other embodiments, the cap is not selective and is disposed one the via ends with the use of, for example, a mask. In some embodiments, the vias are recessed from the surface (e.g., back side) of the substrate relative to the rest of the substrate, before a cap is disposed onto the back side of the vias. In such embodiments, the cap fills the recess. In some embodiments, the cap has a width that substantially matches a width of the via onto which it is disposed. In other embodiments, the cap has a width greater than the width of the via onto which it is disposed. After the cap is disposed onto the ends of the vias, the substrate is further processed to prepare it for bonding, e.g., hybrid bonding. Such processing can include etching the substrate relative to the capped vias, which makes the vias protrude from the substrate at the back side. In embodiments in which the caps are wider than the vias onto which they are disposed, the portion of the substrate covered by the cap will be protected from the substrate etching. In such embodiments, the non-etched substrate protected by the cap forms a semiconductor sleeve around the via ends. After the substrate is etched relative to the vias, temporary caps can be removed and a dielectric layer is disposed onto the back side of the substrate, filling in the etched substrate and covering the TSVs. The dielectric layer laterally supports the TSVs. The dielectric layer on the top of the TSVs can then be planarized to reveal the conductive layer within the TSVs. In some embodiments, the caps need not be (fully) removed, such that the cap material, different from the remainder of the via, can remain in the microelectronic structure element.

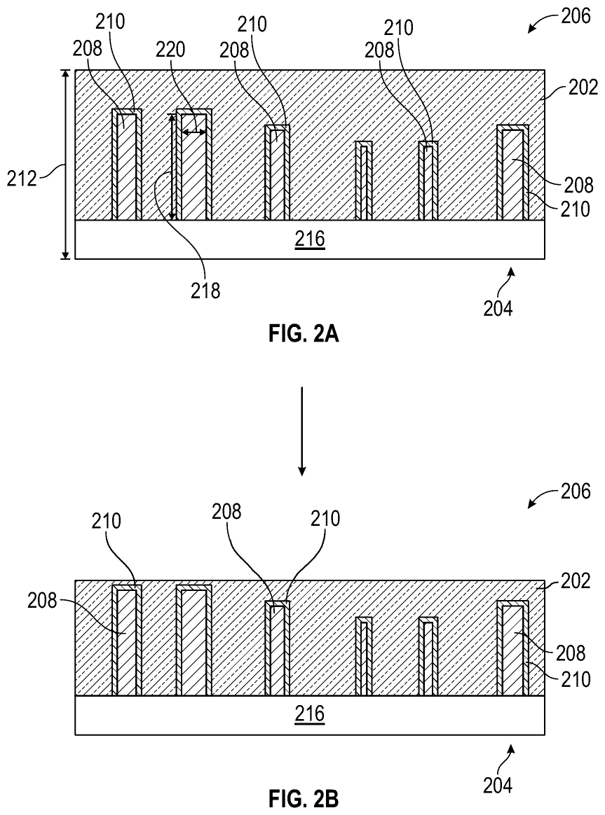

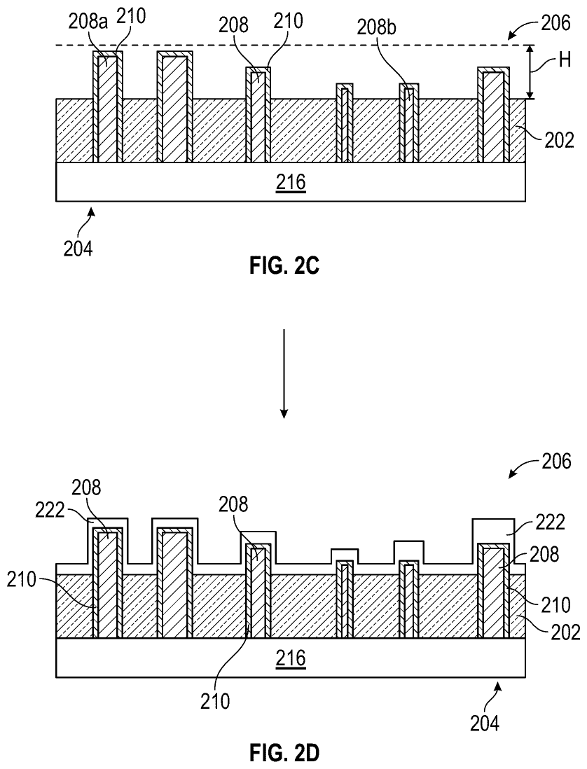

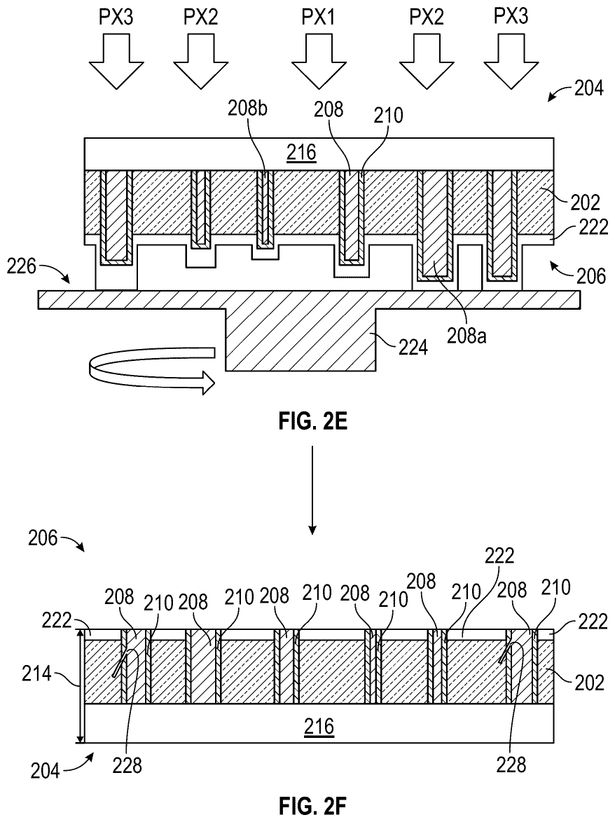

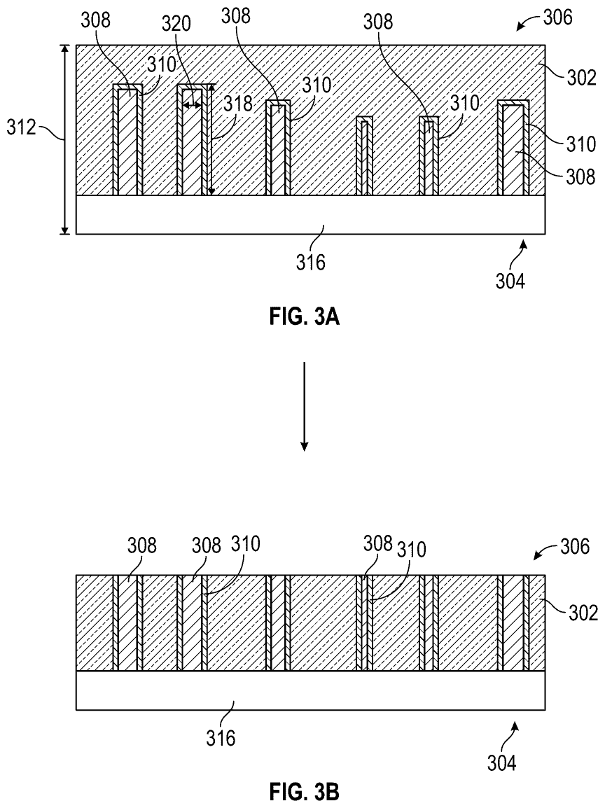

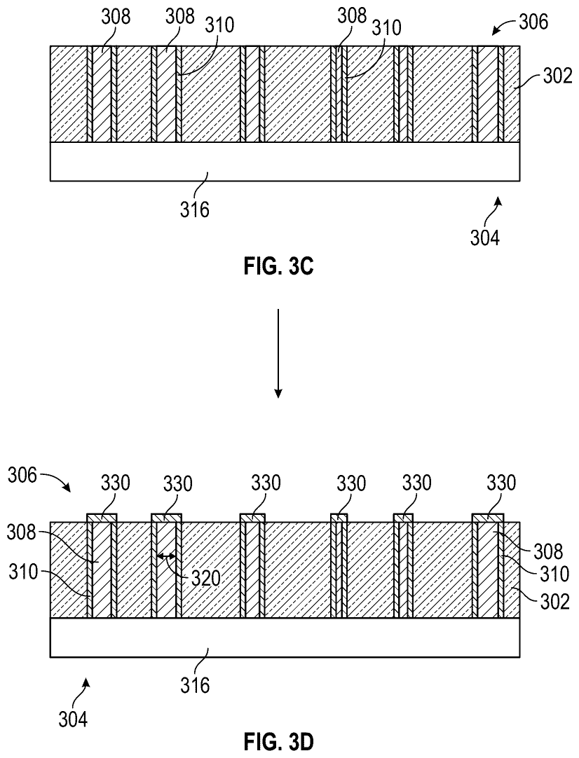

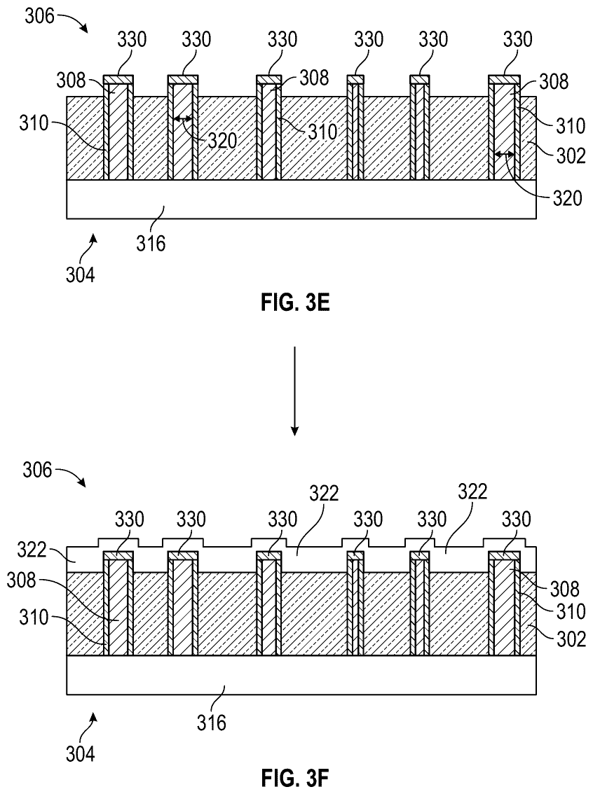

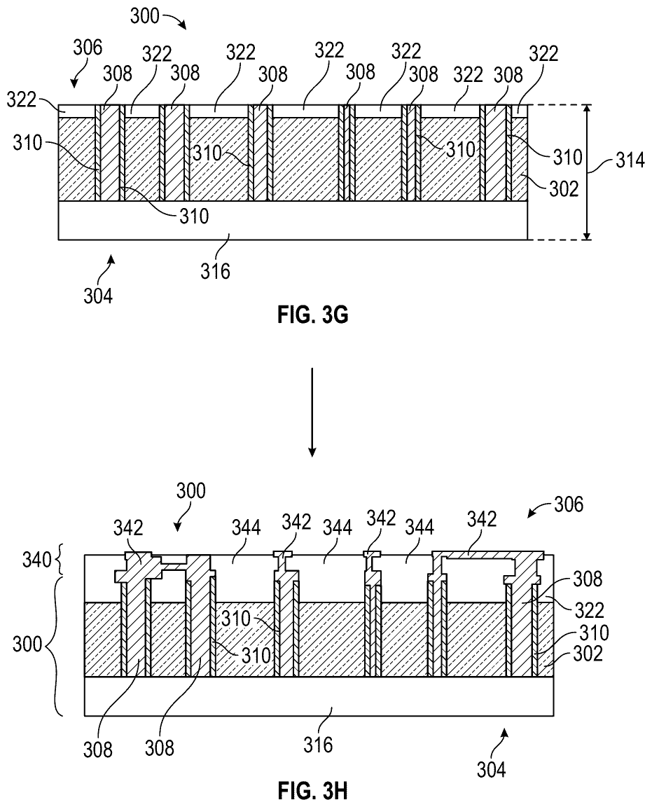

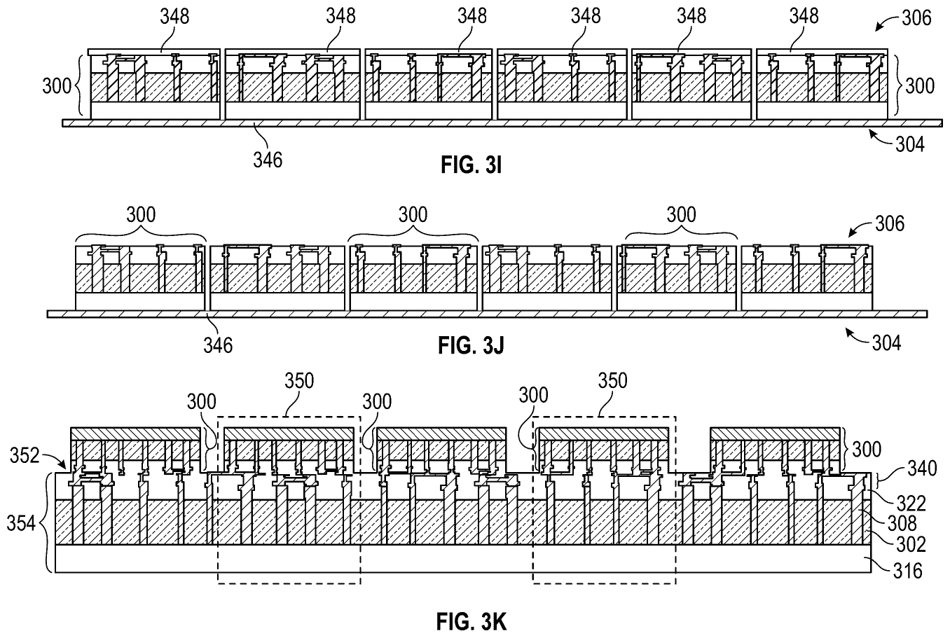

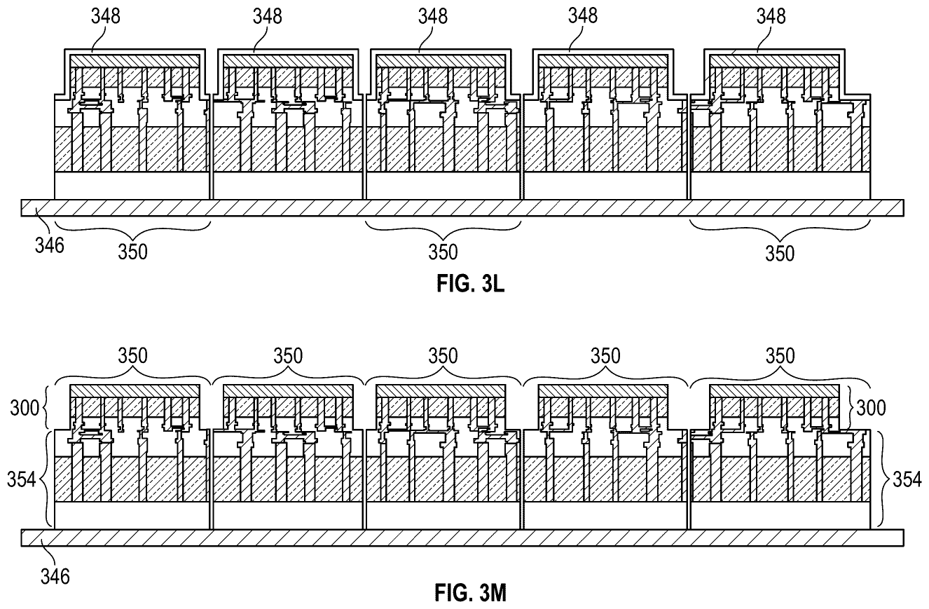

FIGS. 2A-2F schematically present a method of processing the back side of a substrate to form a microelectronic structure, such as a semiconductor element (e.g., wafer or die). The starting structure schematically presented in FIG. 2A can be the same as the starting structure for the embodiments disclosed below with respect to FIGS. 3A-7F. FIG. 2A shows a bulk semiconductor portion 202 with a front side 204 and a back side 206 opposite the front side 204. By convention, the front side 204 of the bulk semiconductor portion 202 has devices, such as transistors. FIG. 2A also shows a plurality of conductive via structures extending from the front side 204 of the bulk semiconductor portion 202 toward the back side 206 of the bulk semiconductor portion 202. The conductive via structures of the illustrated embodiments comprise TSVs 208, but the embodiments are not so limited. The TSVs 208 are lined with TSV liners 210, which separate the TSVs 208 from the bulk semiconductor portion 202. The TSV liners 210 can include adhesive layers and/or barrier layers. The substrate has a preliminary thickness 212 that is greater than the thickness of the intended final (post-thinning) thickness 214 (FIG. 2F) of the element being fabricated. On the front side 204 of the bulk semiconductor portion 202 is at least one BEOL layer 216, as described above. The BEOL layer 216 is optional and may be absent, e.g., if the microelectronic structure is a standalone or surface mount device, as are many passive components.

The bulk semiconductor portion 202 can comprise a wafer of semiconductor material (e.g., silicon, III-V materials, or more exotic compound materials employed for optical devices), or can comprise materials such as glass, ceramic, or other suitable materials. The substrate may include active transistors, passive devices, or may act as a carrier, bridge, or an interposer.

The TSVs 208 can be referred to as vias, through-substrate vias, or TSVs. As shown in FIG. 2A, the TSVs 208 can vary in depth 218 and width 220, including deeper TSVs and shallower TSVs. For example, an average depth 218 of TSVs 208 may be between 0.5-5 μm, between 5-50 μm, between 40-50 μm, or between 10-150 μm, or deeper. In some embodiments, the TSVs can have relatively high non-uniformity, such as up to several microns in thickness. Due to the process variations or tool limitations, there can be significant differences in the depths 218 of the TSVs 208. TSVs 208 of different diameters or widths 220 across the substrate can also contribute to variations in depths 218 of the TSVs 208. The TSVs 208 can be fully or partially lined with TSV liners 210. The TSV liners 210 can include, for example, a dielectric and/or conductive adhesion and barrier layers. For some insulative substrates, such as glass or glass ceramic materials, the insulative liner may be omitted in the TSV structure. In some embodiments, a very thin layer of titanium or tantalum or related compounds may be coated on the sidewall of the TSV, to serve as an adhesion layer between the substrate and the bulk TSV conductor. The TSV liners 210 can serve as diffusion barriers, reducing or eliminating diffusion or electromigration of the materials composing the TSVs 208 into the bulk semiconductor portion 202. For copper TSVs in silicon substrates, the TSV cavities can be etched in the bulk semiconductor portion 202 and the cavity can be coated with a dielectric layer to insulate the conductive copper layer of the TSV 208 from the bulk semiconductor portion 202. After forming such an insulating liner, a barrier and/or adhesion layer is typically coated on the liner prior to filling the cavity with the conductive layer of the TSV 208, such that the TSV liners 210 can comprise both insulating and barrier/adhesion materials. Copper, in particular, is desirably confined by barrier materials (such as silicon nitride, metal nitride, or non-copper metals) to prevent diffusion into the bulk semiconductor portion 202 where it can adversely affect active devices. In some embodiments, the widths 220 (lateral dimension) of TSVs 208 or may vary. Within the design or layout of the TSVs 208, some TSV widths 220, for example, via diameters, may be 10% to 40% smaller than their neighbors. For example, the diameter of a first array of TSVs may be smaller than the diameter of a second array of TSVs. In practice, after the via forming process, for example by RIE methods, the depth of the smaller vias may be smaller than the depth of the larger vias. In some embodiments the variation in the depth of the vias may range from 3 μm to more than 10 μm. In some embodiments, the larger vias are adapted to supply power or ground or both, and in some embodiments, the smaller vias are adapted for signals. The TSVs 208 are electrically conductive and can comprise a conductive metal, such as copper, gold, silver, nickel, aluminum, tungsten, polysilicon, metal silicide or alloys thereof. In some embodiments, the TSVs are predominantly copper, such as greater that 50 atomic percent copper, greater than 60 atomic percent copper, or greater than 90 atomic percent copper.

FIG. 2B shows the structure of FIG. 2A after being thinned from the back side 206 of the bulk semiconductor portion 202. The bulk semiconductor portion 202 can be thinned, for example, by grinding and/or polishing, such as CMP. FIG. 2B shows only the bulk semiconductor portion 202 as having been thinned. For example, the thinning process can be timed to stop before revealing any vias, or can proceed until the deepest of the vias are revealed. In FIG. 2B, the TSVs 208 have not been (significantly) thinned. Further thinning in the illustrated process is avoided in order to minimize risk of smearing TSV material, such as copper, across the back side 206 of the bulk semiconductor portion 202.

FIG. 2C shows the structure of FIG. 2B after substrate-selective etching (e.g., an etch-back). The back side 206 of the bulk semiconductor portion 202 can be exposed to a substrate-selective etchant, which preferentially etches the bulk semiconductor portion 202 compared to the TSVs 208 and/or TSV liners 210. This etch-back step reduces the thickness of the bulk semiconductor substrate by a reduced thickness H. One suitable substrate-selective etchant can be SF6, particularly if the bulk semiconductor portion 202 comprises silicon.

The etch-back step reveals the TSVs 208 at the back side 206 of the bulk semiconductor portion 202, such that the TSVs 208 protrude from the back side 206 of the bulk semiconductor portion 202. The deeper TSVs (e.g., TSV 208a) will protrude from the bulk semiconductor portion 202 more than the shallower TSVs (e.g., TSV 208b) will. In some embodiments, the bulk semiconductor portion is etched by reduced thickness H, such that the shallower TSVs protrude from the bulk semiconductor portion at the back side, for example by between 2 and 3 microns. It will be understood by the skilled artisan that during the etch-back step, the deeper TSVs (e.g., TSV 208a) will be revealed before the shallower TSVs (e.g., TSV 208b) will be revealed. The TSV liners 210 are exposed to the substrate-selective etchant. The TSV liner material nearer to the back side 206 will be exposed to the substrate-selective etchant for longer periods than the TSV liner material nearer to the front side 204. Long etching times can be required to remove a reduced thickness H from the bulk semiconductor portion 202 at the back side 206. A consequence of this process is that the TSV liner material—especially the TSV liner material near the back side 206 of the thicker TSVs (e.g., TSV 208a)—can be exposed to the substrate-selective etchant for long periods. Even though the substrate-selective etchant etches preferentially etches the bulk semiconductor portion 202 compared to the TSV liners 210 and the TSVs 208, the TSV liners 210 can be damaged (e.g., partially or fully etched in some places) by prolonged exposure to the substrate-selective etchant, as the selectivity is typically not perfect. For example, if the TSV liner 210 is 100 nm thick and the reduced thickness His 10,000 nm, the ratio of etching between the bulk semiconductor portion 202 compared to the TSV liner 210 of less than 100:1 can risk complete removal of the TSV liner 210, and of course even higher selectivity can cause significant damage or loss of the TSV liner 210 over a portion of the TSV 208.

FIG. 2D shows the structure of FIG. 2C after a dielectric layer 222 is disposed over its back side 206. The dielectric layer 222 can have a thickness of between approximately 3 microns and approximately 5 microns. The dielectric layer 222 increases the stress on the TSVs 208 and the bulk semiconductor portion 202. The dielectric layer 222 can comprise, for example, an initial thin silicon nitride layer to serve as a barrier and/or etch stop, and a thicker silicon oxide layer thereover. Other materials (e.g., silicon oxynitride, silicon carbonitride, polymeric materials, etc.) are possible.

FIG. 2E shows the structure of FIG. 2D up-side-down and being planarized at the back side 206. The planarization of the back side 206 includes the back side 206 being put into contact with a polisher 224, then applying loads (e.g., PX1, PX2, and PX3) to the front side 204 to keep the structure in contact with the polisher 224. The polisher 224 mechanically thins the back side 206 of the structure, for example, by having a rough surface 226 that is moved relative to the structure, e.g., by vibration or spinning. The planarization can be, for example, CMP, to form a smooth hybrid bonding surface at the back side 206.

It will be understood by the skilled artisan that different amounts of TSV protrusion subjected to the planarization process can result in different amounts of pressure applied to different TSVs 208 over time, which can increase the incidence of TSV fracture or cracking within the TSV liner 210 of the TSVs 208, especially for the deeper TSVs (e.g., TSV 208a).

FIG. 2F shows a microelectronic structure 200 planarized or polished (e.g., prepared for hybrid bonding) at the back side 206, formed by the method schematically presented in FIGS. 2A-2F. The microelectronic structure 200 can exhibit cracks 228 in the TSV liner 210 in multiple places, resulting at least in part from the high pressure placed on the deeper TSVs (e.g., TSV 208a) during the planarization step shown in FIG. 2E. These cracks 228 in the TSV liner 210 are a manufacturing defect; the material of the TSVs 208, e.g., copper, can migrate out of the TSV 208 to contaminate the bulk semiconductor portion 202.

FIGS. 3A-3G schematically present a method of processing the back side 306 of a substrate to form a microelectronic structure 300, in accordance with one embodiment. In this method, a backside 306 of a bulk semiconductor portion 302 can be thinned to expose embedded TSVs 308 and prepared for hybrid bonding, using selective temporary backside caps. FIG. 3A is similar to FIG. 2A with reference numbers for similar features incremented by 100. As discussed above, the plurality of TSVs 308 can have variable dimensions, such as depth 218 and width 220. The depths 218 of TSVs 308 within a single substrate can vary, for example, by more than 1 micron, for example from 2 microns to 10 microns, or by at least approximately 10% of the height of TSVs 308. The widths 220 of TSVs 308 within a single substrate can also vary, for example, by approximately 100% or more relative to the smallest of the vias. The widths 220 of TSVs 308 within a single substrate can vary, for example, by 0.3 microns to 20 microns, or by at least approximately 5%.

FIG. 3B shows the structure of FIG. 3A after being thinned to expose all TSVs 308 at the back side 306. This back side thinning step is different from that shown in FIG. 2B, at least in part because the back side thinning shown in FIG. 2B exposed few or none of the TSVs 208. This back side thinning or CMP can include low temperature back side grinding and/or low temperature CMP to expose all TSVs 308 and form a relatively smooth back side surface without excessive variation in TSV protrusion. The low temperature CMP process can be applied with high concentrations of metal complexing agents. The polishing temperature may range from −20° C. to 20° C. or between −5° C. to 15° C. The complexing agent concentration may range between 50 ppm to more than 10,000 ppm. The metal complexing agents can comprise benzotriazole (BTA) or other azole or triazole moieties. More than one type of complexing agent may be used during the backside thinning process. A high complexing agent concentration suppresses potential interaction of the metal of the TSVs 308 with the bulk semiconductor portion 302, thus avoiding contamination of the bulk semiconductor portion 302 while passivating the surface of the TSV metal.

FIG. 3C is similar to FIG. 3B, but schematically shows the back side being cleaned. In this cleaning step, the back side 306 of the substrate is cleaned to remove any potential TSV material (e.g., copper) left on other substrate surfaces by the thinning process. The cleaning step may comprise cleaning the substrate with an acid solution, for example 1% to 10% sulfuric acid or nitric or sulfuric acid or buffered HF. The cleaning method or agent should minimize the dissolution of the metal of the TSVs 308, which could undesirably form recesses that are too deep. This cleaning of the back side 306 of the substrate can include recessing the substrate at the back side 306 by a small, precise amount. In some embodiments, the recess can be less than 35 nm, or between approximately 30 nm and 40 nm, or between approximately 25 nm and 100 nm. In some embodiments, the back side of the substrate can be cleaned of contamination (e.g., copper contamination) using, for example, a high-pH solution, for example a resist developer solution. In some embodiments, the back side of the substrate can be cleaned using cleaning chemistries comprising combinations of dilute buffered hydrofluoric acid and inorganic or organic acids. The choice of the acids is such that the formulated chemistry will clean off the metallic contaminants from the backside without attacking or etching the semiconductor portion. In some embodiments a high-pH solution with or without suitable surfactant may be applied to clean the backside of the substrate. After the cleaning step, the substrate can be rinsed with deionized water and dried. In some implementations the acidic cleaning and high pH cleaning processes may be applied in any chosen sequence.

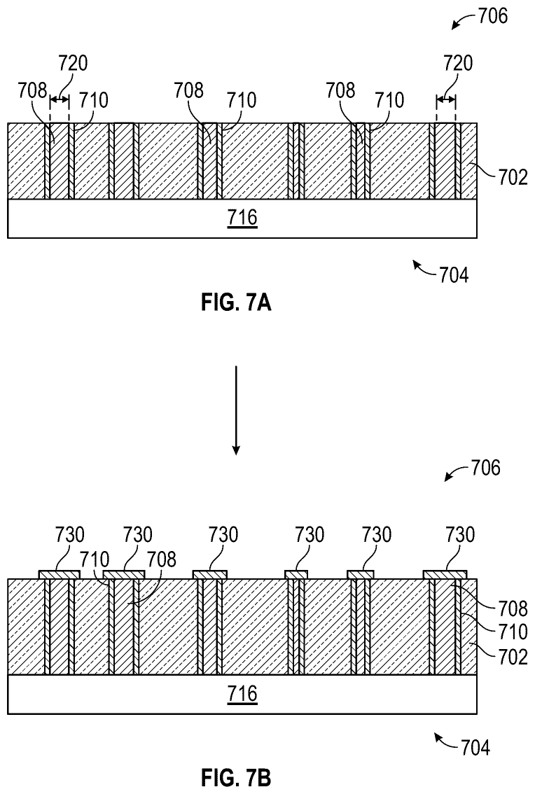

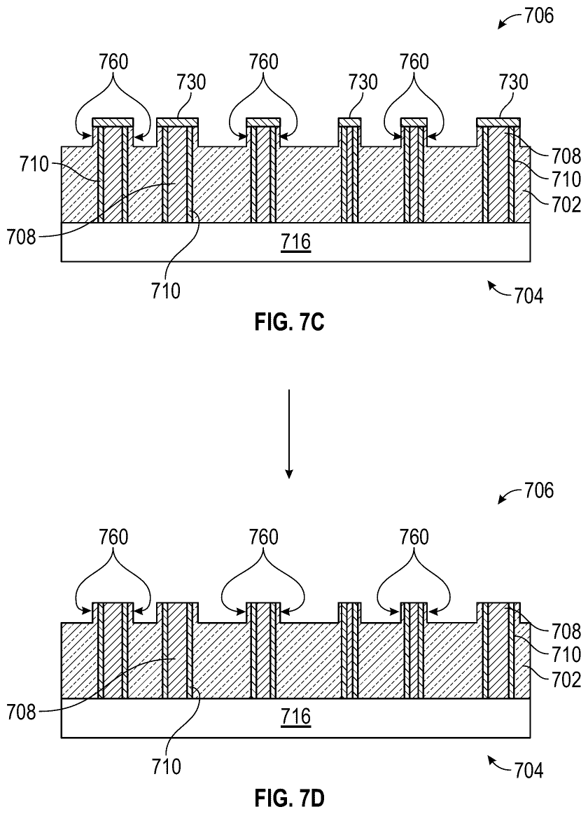

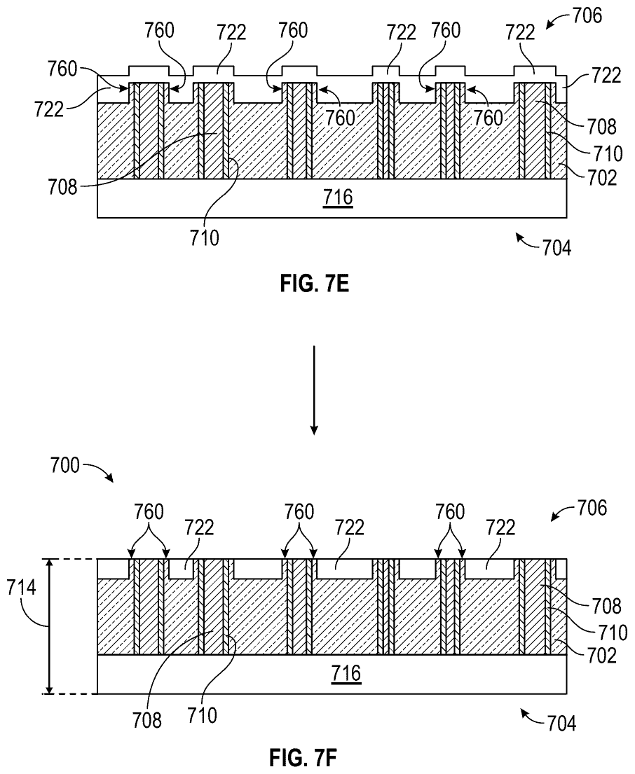

FIGS. 3D-3G show the deposition of a dielectric layer 322 over the bulk semiconductor portion 302 at the back side 306, for example, to prepare the back side 306 of the substrate for hybrid bonding. FIG. 3D shows formation of a protective cap 330 on the back side 306 of the TSVs 308. Formation of a protective cap 330 can include formation of a selective cap (e.g., a cap formed of a material that selectively attaches to the TSV 308 compared to the bulk semiconductor portion 302) or formation of a patterned cap (e.g., a cap of patterned mask, e.g., an organic resist, as shown in FIG. 7B). Selective caps can be formed of material that selectively attaches to the TSV 308 (e.g., copper), as compared to the bulk semiconductor portion 302 (e.g., silicon). In some embodiments, a selective cap may comprise an adsorbed organic metal complexing agent. In some embodiments, the adsorbed organic metal complexing agent is from the cleaning step. In some embodiments, the cleaned substrate may be exposed to a solution comprising a high concentration of the complexing solution. In some embodiments, the cleaned substrate may be exposed to a solution comprising a high concentration of the complexing solution only briefly. For example, a cleaned substrate may be exposed to an organic material, such as benzotriazole (BTA), for example less than 30 second to form a BTA selective cap layer. The concentration of the complexing agent may range from 50 ppm to over 10,000 ppm.

In other embodiments, selective caps can comprise a dielectric material capable of selective formation, for example an organic material, such as benzotriazole (BTA). The process of depositing BTA onto the back side 306 of the TSVs 308 is self-limiting: it will stop after the selective formation of a cap only a few monolayers in thickness. BTA forms a substantially transparent, colorless layer on the back side 306 of the TSV 308.

In some embodiments, selective caps can comprise a metal layer, such as CoP, NiP, NiW, Ni, Co, or combinations thereof. In some embodiments, the back surface of the substrate may cleaned in a high-pH solution, such as a resist developer, to clean any residual complexing agent from the exposed surface of the metal of the TSVs 308. The cleaned surface can be selectively capped by exposing the backside of the substrate to a dilute electroless metal chemical solution for a period of less than 10 minutes, less than 5 minutes, or less than 120seconds. The temperature of the electroless plating solution may range between 40° C. and 90° C. For selective capping of the TSV pads the electroless plating chemistry may be more diluted than usual to prevent the bridging between metals of adjacent TSVs 308 by the protective cap 330. The dilution of the electroless bath may range between 150% to 500%. Diluents can comprise de-ionized water, however other diluents may be used. In some embodiments, the back surface of the bulk semiconductor portion 302 may be briefly activated by exposing the cleaned substrate to an acidic dilute solution of palladium sulfate. After such an activation exposure, the substrate can be rinsed with de-ionized water and dried. The activated surface can then be capped with a metal layer from a plating solution. The thickness of the metal selective caps can be controlled by controlling the deposition time and the temperature of the electroless bath. The longer the plating time, the greater the thickness of the capping layer. The capping layer thickness may vary between 5 nm to 1,000 nm. In practice, a capping layer of less than 50 nm, such as 10 nm to 50 nm, may be adequate.

Selective caps (e.g., metallic caps such as NiP or dielectric caps such as BTA) can be deposited onto the back side 306 of the TSVs 308 by various methods, e.g., electroless deposition, including spray or immersion. First the back side 306 of the substrate can be sprayed with dilute palladium sulfate for approximately 10 seconds. Then the back side 306 of the substrate can be sprayed with or immersed in a selective cap precursor material (e.g., NiP electroless solution or BTA solution). In some embodiments using BTA solution, the BTA solution is 0.1% BTA or higher.

In some embodiments, the protective capping layer may be formed by atomic layer deposition methods (ALD) or other conformal deposition techniques.

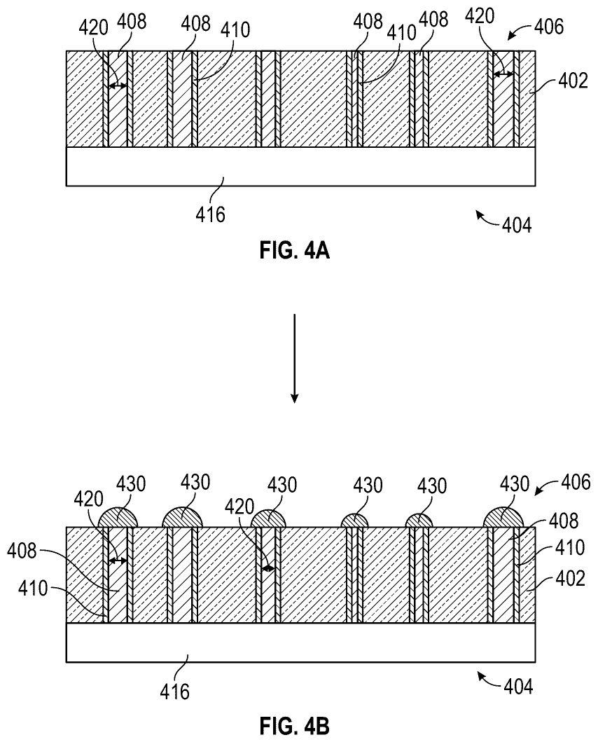

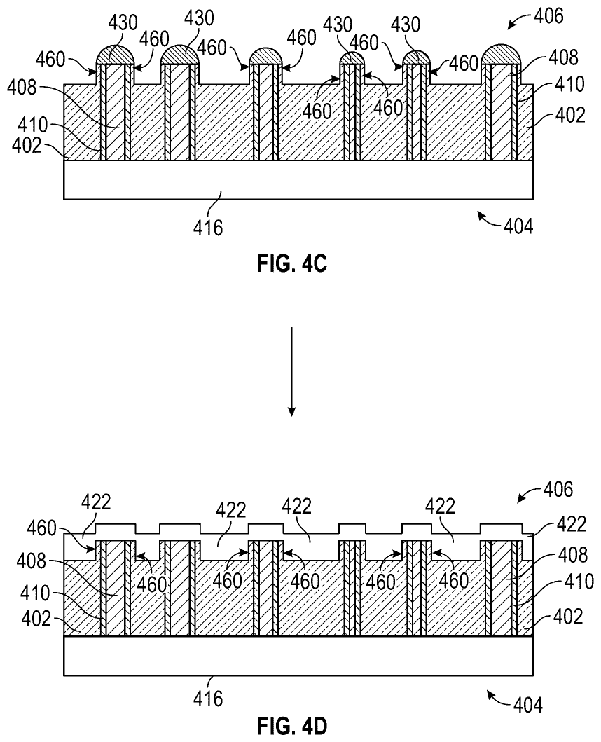

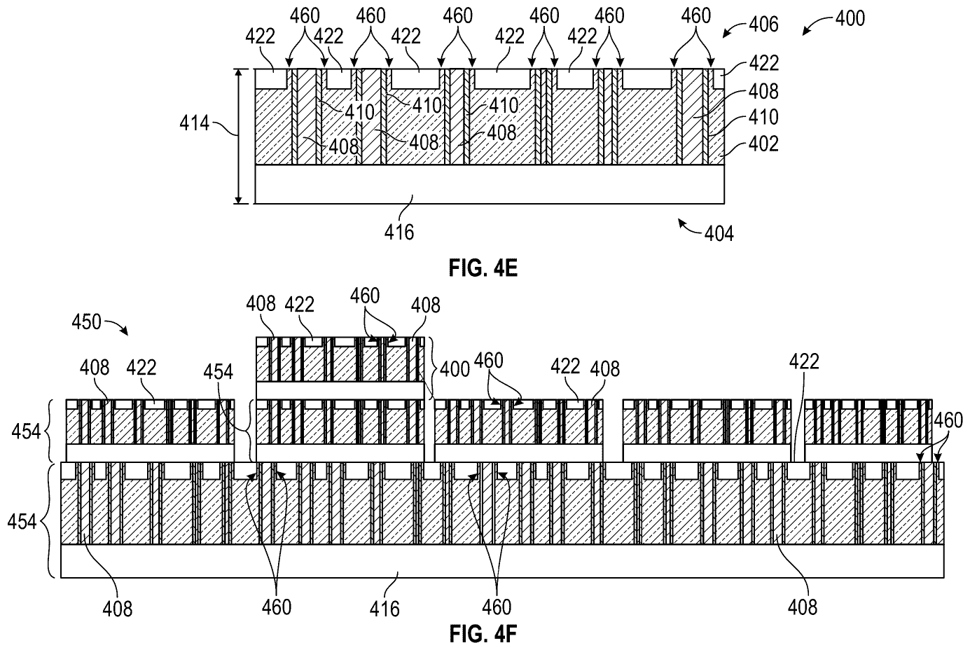

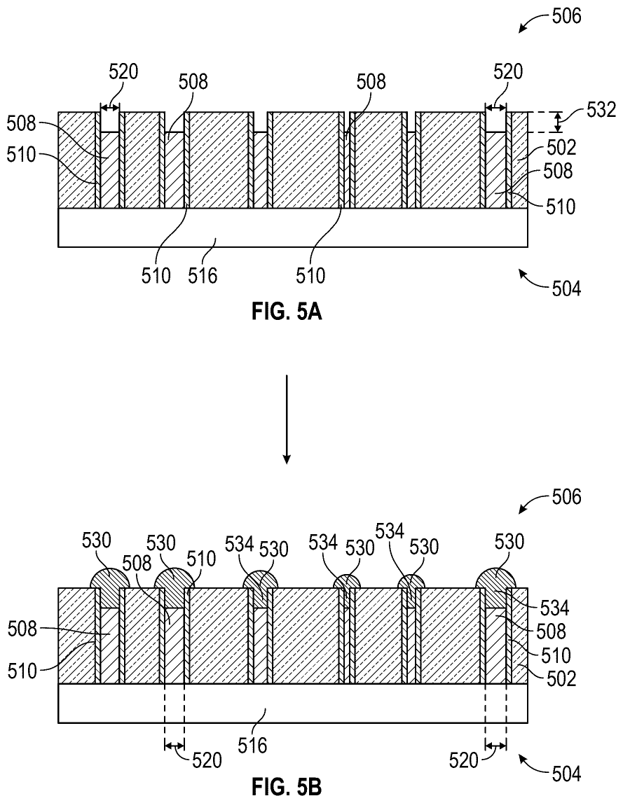

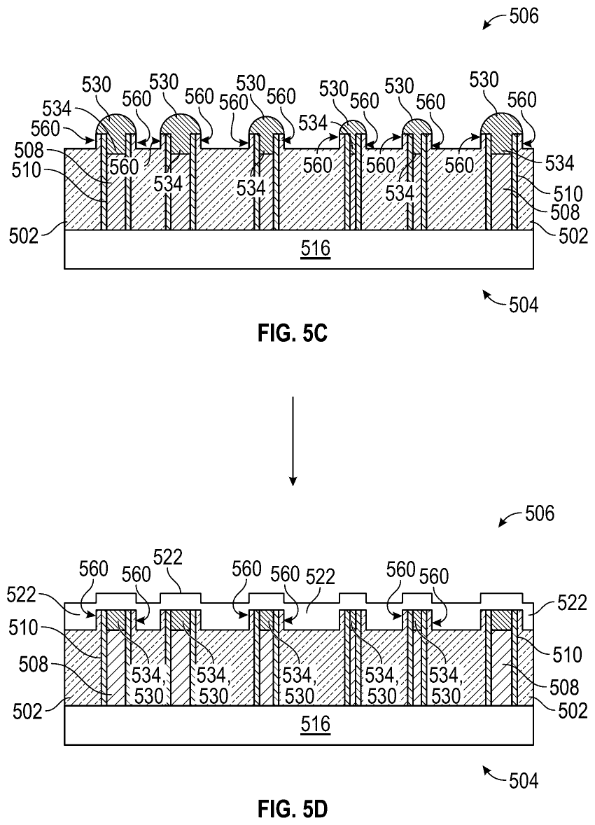

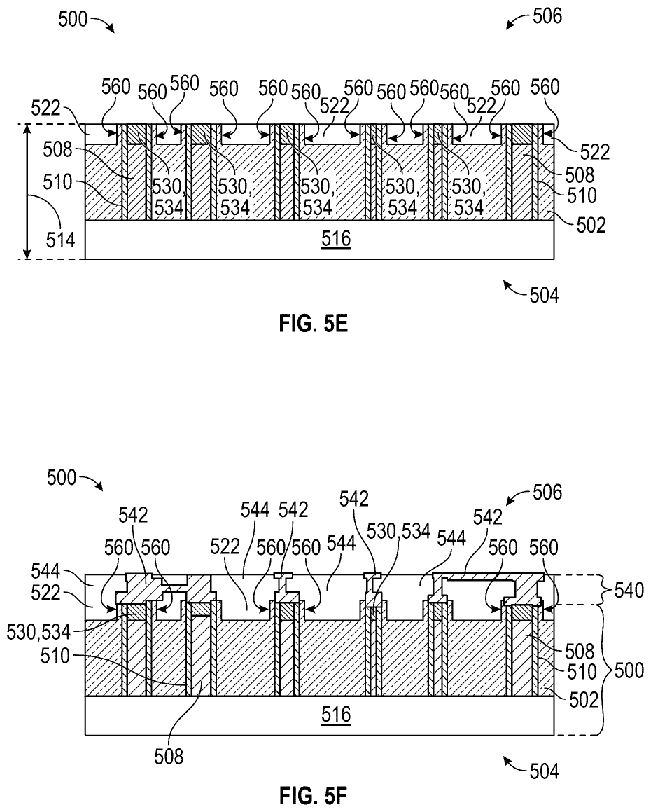

Protective caps (e.g., patterned caps and selective caps) can vary in width. Patterned caps (e.g., caps patterned by or formed of resist) can have essentially any width a mask can support, and can be arranged to be greater than or equal to the width 320 of the TSVs 308. Selective caps can also vary in width. Because BTA deposition is a self-limiting reaction, a selective cap comprising BTA can have a width substantially the same as the width 320 of the TSV 308 over which it is disposed. In other words, a selective cap comprising BTA substantially covers the TSV 308 but will not cover appreciable amounts of the bulk semiconductor portion 302 adjacent to the TSVs 308. Formation of selective caps by some non-self-limiting deposition methods, such as electroless deposition of cap materials that include metals (such as NiP or CoP), are different, since the deposition process may not be a self-limiting reaction. Selective caps that include metal (such as NiP or CoP) can grow as the deposition reaction is allowed to continue. After a first period, the selective cap will substantially cover the TSV 308 exposed at the back side 306, but if the deposition reaction continues, the cap will grow laterally and vertically into a hemisphere-like shape on the back side 306 of the TSV 308, or “mushroom” (as shown in FIGS. 4B and 5B). In other words, the formation of a selective cap by some plating methods, including electroless deposition of cap materials comprising metal (e.g., NiP or CoP), can start by substantially covering the exposed surface of the TSV 308, but if allowed, the cap will grow to also cover an increasing amount of bulk semiconductor portion 302 adjacent to the TSVs 308. Caps that cover not only the back surface of a TSV 308 but also part of the bulk semiconductor portion 302 adjacent to the TSV 308 can be considered “overcoated.”

The protective cap 330 shown in FIG. 3D is a selective cap 330 that substantially covers the revealed back side 306 of the TSVs 308, without significant encroachment over adjacent bulk semiconductor portions 302. For example, the selective caps 330 of FIG. 3D can be less than or equal to 107%, between about 100% and 110%, or between 100% and 105% of the width of the corresponding TSVs 308. Such a selective cap 330 can be formed, for example, of BTA. Such a selective cap 330 can alternatively be a selective cap including metal (e.g., NiP or CoP), as long as a non-self-limiting deposition process is timed to prevent the selective cap from growing laterally (e.g., to mushroom) by any significant amount.

FIG. 3E shows the structure of FIG. 3D after the bulk semiconductor portion 302 is etched from the back side 306. The bulk semiconductor portion 302 (e.g., silicon) is etched preferentially compared to the TSV 308 with a cap 330 disposed thereon. FIG. 3E shows etching of the back side 306 of the bulk semiconductor portion 302 while the protective caps 330 cover the conductive TSVs 308 to form protruding TSVs 308. Indeed, the protective caps 330 protect the back surface of the TSVs 308 from the etch, forming protruded TSVs 330. The TSVs 308 can have different widths 320, which is true of each step and each embodiment disclosed herein. One suitable etchant that preferentially etches silicon includes SF₆. The bulk semiconductor portion 302 can be directionally etched (e.g., by reactive ion etching or plasma etching). In some embodiments, the bulk semiconductor portion 302 can be etched such that the TSVs 308 protrude above the back side 306 of the bulk semiconductor portion 302 by less than 1 micron, less than 10 microns, or between 50 nm and 2 microns, or between 500 nm and 15 microns.

FIG. 3F shows a dielectric layer 322 disposed over the back side 306. The dielectric layer 322 can include any of the dielectric bonding materials described above, and can also serve to aid in planarization and subsequent bonding, for example, direct bonding, e.g., hybrid bonding. In some embodiments, the dielectric layer 322 can comprise an initial thin silicon nitride layer to serve as a barrier and/or adhesion layer, and a thicker silicon oxide layer thereover. In some embodiments, a silicon oxide layer is deposited directly over the back sides of the TSVs 308 (including protective caps 330) and of the bulk semiconductor portion 302. In some other embodiments, thin silicon oxynitride or silicon carbonitride layers may also be deposited on top of the oxide layer or embedded within the dielectric layer. The dielectric layer in some embodiments can comprise layers of inorganic materials and polymeric materials. The polymeric material may comprise, for example, a high temperature polyimide, BCB or epoxide coating, amongst other materials. The dielectric layer 322 fills in the space etched from the bulk semiconductor portion 302 in the previous step (shown in FIG. 3E). The dielectric layer 322 is also disposed over the TSVs 308 with protective caps 330 disposed thereon.

FIG. 3G shows the structure of FIG. 3F after being planarized at the back side 306 to reveal the TSVs 308. In FIG. 3G, the planarization process also includes removing the selective cap 330 (shown in FIG. 3F). However, the cap need not be removed in other embodiments, as shown in FIG. 5E. FIG. 3G shows a microelectronic structure 300 with a final thickness 314 and a planarized back side 306 that is, for example, prepared for hybrid bonding, as discussed above. The planarization process can include a dielectric CMP process to form a smooth hybrid bonding surface, and the surface can also be treated (e.g., activated and/or terminated) as described above if this surface is to be hybrid bonded without further layers. Each of the TSVs 308 shown in the microelectronic structure 300 of FIG. 3G is separated from the bulk semiconductor portion 302 by a TSV liner 310. The TSV liners 310 in the microelectronic structure 300 lack stress cracking (e.g., without the cracks 228 shown in FIG. 2F) due in part to the protective caps 330 and due in part to the process whereby the TSVs 308 (especially TSVs of variable dimensions) are of relatively constant height at the time of the planarization. Additionally, the thickness of the dielectric layer 322 in the microelectronic structure 300 can be approximately less than 100 nm, less than 10 microns, or between 50 nm and 2 microns, or between 500 nm and 15 microns. It will be understood by a skilled artisan that the thickness of the dielectric layer 322 can be similar to the protrusion of the TSVs above the back side 306 of the bulk semiconductor portion 302 shown in FIG. 3E, or slightly less to the extent the planarization removes small amounts of the TSVs 308. In some embodiments, the back surface of the microelectronic structure has dielectric regions and conductive regions, as shown. The dielectric regions are the back surface of the dielectric layer 322. The conductive regions are the back surfaces of the TSVs 308. In other embodiments with permanent caps (shown, e.g., in FIG. 5E), the conductive regions can be the back surfaces of the caps.

FIG. 3H shows further back side processing, such as the formation of an RDL structure 340 on the back side 306 of the microelectronic structure 300 shown in FIG. 3G. The RDL structure 340 includes conductive portions 342 and nonconductive portions 344, and can include one or more metallization levels and intervening dielectrics. A microelectronic structure 300 including the RDL structure 340 can still be a microelectronic structure 300; the term for the structure and reference numeral attached to the structure can be the same regardless of whether RDL is included. While RDLs are not illustrated on the back side of each and every microelectronic structure disclosed herein, it will be understood by the skilled artisan that an RDL can be formed on the back side of any microelectronic structure disclosed herein. If RDL is included, then the backside planarization at the stage of FIG. 3G need not be to the standards for direct bonding, and instead the RDL itself is prepared (polished to very low surface roughness, possibly activated and/or terminated) for hybrid bonding.

FIG. 3I shows coated and singulated microelectronic structures 300. FIG. 3H shows one microelectronic structure 300 with the RDL structure 340 at the back side 306. The skilled artisan will appreciate that the microelectronic structure 300 of FIGS. 3A-3H can represent a larger substrate (e.g., a wafer) to be singulated. FIG. 3I shows such a larger substrate as the microelectronic structure 300 after its front side 304 has been mounted onto a dicing frame 346, a protective layer 348 (e.g., a resist coating layer) has been disposed over the back side 306, and the individual dies have been singulated (e.g., diced) from the larger substrate. The dies themselves can also be considered microelectronic structures 300.

FIG. 3J shows the singulated microelectronic structures 300 of FIG. 3I after the protective layer 348 has been removed from the back side 306 of each singulated microelectronic structure 300. The protective layer removal process may comprise dissolving the protective layer in a suitable solvent and rinsing and drying the substrate. In some embodiments, the substrate is spin dried. Each singulated microelectronic structure 300 can be removed from the dicing frame 346. The back surface of the microelectronic structures 300 can be further prepared for hybrid bonding (e.g., cleaned, activated, and/or terminated), although in some arrangements only one of the two surfaces to be bonded is so treated.

The microelectronic structures 300 can be bonded to other components. FIGS. 3K-3M illustrate the formation of singulated bonded structures. While not every microelectronic structure of the various embodiments herein (e.g., microelectronic structures 500, 600, 700) is illustrated herein as being bonded to other components to form a bonded structure, it will be understood by the skilled artisan that any microelectronic structure disclosed herein can be bonded to other components to form bonded structures. FIG. 3K shows multiple pre-singulated bonded structures 350, each comprising one die from FIG. 3J hybrid bonded onto a prepared back surface 352 of a second substrate 354. The second substrate 354 can be a larger substrate, e.g. a wafer. FIG. 3K shows the microelectronic structures 300 bonded to the second substrate 354 in a back-to-back configuration, to form pre-singulated bonded structures 350. The second substrate 354 shown in FIG. 3K has a BEOL layer 316 on its front side, a bulk semiconductor portion 302, a dielectric layer 322, an RDL structure 340 and TSVs 308 electrically connecting the BEOL 316 or active devices of the second substrate 354 to the RDL structure 340. The TSVs 308 of the second substrate 354 can be separated from the bulk semiconductor portion 302 of the second substrate 354 by TSV liners (not shown). Before the microelectronic structures 300 are bonded to the back surface 352 of the second substrate 354, the back surface 352 of the second substrate 354 is prepared for hybrid bonding, as discussed above. After the microelectronic structures 300 are deposited onto the back surface 352 of the second substrate 354, the hybrid bonding process can be completed by, for example, annealing the structure at higher temperature, as discussed above. In some embodiments, the singulated structure of FIG. 3G without an RDL layer may be cleaned, prepared, and bonded on the second substrate 354. The bonded structure may be annealed at higher temperatures. The bonded structure may be further singulated, as depicted in FIG. 3M. In some other embodiments additional dies may be bonded on the back surface of the first bonded die.

The structure shown in FIG. 3K is a pre-singulation bonded structure 350. The structure shown in FIG. 3M illustrates a plurality of post-singulation bonded structures 350 (or, interchangeably, a diced bonded structures 350). The phrase “bonded structure” can refer to either the pre-singulation or the post-singulation structure.

FIG. 3L shows the structure of FIG. 3K after it has been mounted onto a dicing frame 346, coated with a protective layer 348 (e.g., resist coating), and singulated into diced bonded structures 350.

FIG. 3M shows the structure of FIG. 3L after the protective layer 348 has been removed. FIG. 3M shows a plurality of diced bonded structures 350, still mounted to the dicing frame 346. Each diced bonded structure 350 comprises a microelectronic structure 300 hybrid bonded to a second substrate 354.

While FIGS. 3K-3M illustrate an example of D2W bonding where both bonded elements comprise semiconductor elements, such as ICs, and both elements comprise TSVs, the skilled artisan will appreciate that the concepts disclosed herein are also applicable to D2D or W2W bonding, that both elements need not include TSVs, and that both elements need not be semiconductor elements (e.g., one of the bonded elements may be a stand-alone device, such as a power switch or a passive device). Additionally, while back-to-back hybrid bonding is illustrated, the skilled artisan will appreciate that the concepts described herein are also applicable to front-to-back hybrid bonding (see FIG. 4F).

FIGS. 4A-4E schematically present a method of processing the back side 406 of a substrate to form a microelectronic structure 400, in accordance with a second embodiment. In this method, a back side 406 of a bulk semiconductor portion 402 can be thinned to expose embedded TSVs 408 and prepared for hybrid bonding, using backside caps 430, which leads to the formation of a semiconductor sleeve 460. FIG. 4A is similar to FIG. 3C.

FIG. 4B shows the formation of the caps 430 on the back side 406 of the TSVs 408. The caps 430 are overcoated, meaning they substantially cover both the back side 406 of the TSVs 408 but also extend laterally to cover part of the bulk semiconductor portion 402 adjacent to the TSVs 408 on the back side 406. The caps 430 can be formed by a selective process, and continued growth (or overcoating) after covering the TSVs 408 results in lateral growth or “mushrooming.” The selective caps 430 can comprise a metal, such as NiP or CoP, for which selective and non-self-limiting deposition processes are readily available. The caps 430 of the illustrated embodiment can be considered temporary or sacrificial because they are absent in the final microelectronic structure 400, shown in FIG. 4E. The process of forming the mushroomed selective caps 430 is discussed above.

FIG. 4B is analogous to FIG. 3D, since they both illustrate depositing a selective cap (e.g., 430) onto the back side (e.g., 406) of the TSVs (e.g., 408). However, the selective caps 330 shown in FIG. 3D have widths that substantially match the widths 320 of the TSVs 308 on which they are disposed; while the selective caps 430 shown in FIG. 4B are overcoated and have mushroomed, and as such have widths greater than the widths 420 of the TSVs 408 on which they are disposed. For example, the selective caps 430 of FIG. 4B can have a width approximately 105% to 120%, or approximately 110% to 130% the width 420 of the corresponding TSVs 408. The material of the selective caps 430 shown in FIG. 4B are formed by plating methods, for example NiP electroless solution immersion or spray to form a mushroomed cap structure on the back side 406 of the TSVs 408.

FIG. 4C is analogous to FIG. 3E, insofar as they both illustrate recessing the bulk semiconductor portion (e.g., 402) from the back side (e.g., 406). However, in FIG. 4C, the selective caps 430 also substantially cover a portion of the bulk semiconductor portion 402 around each TSV 408. When employing directional etching such as RIE to recess the bulk semiconductor portion 402, the caps 430 shadow the semiconductor and a sleeve 460 of the bulk semiconductor portion 402 surrounding each TSV 408 is not etched and remains intact. The sleeve 460 is, for example, the remaining part of the bulk semiconductor portion 402 surrounding the sidewall of the protruding TSV 408 and/or TSV liner 410 after the bulk semiconductor portion 402 is etched to form protruding TSVs 408. The sleeve 460 can surround the TSV 408 and/or TSV liner 410. The sleeve 460 can have a substantially annular cross-section. It will be understood by a skilled artisan that an annular sleeve 460 can be rectangular or other shaped to conform to the shape of the TSV 408 (e.g., circular, ovular, rectangular, square, etc.). In some embodiments, the width of the semiconductor sleeve (thickness of the annulus wall) is at least about 5%, is in a range of about 5% to 20%, or approximately 10% to 30% or more of the width 420 of the corresponding TSV 408, such as between about 0.5 nm and 100 nm. In some embodiments, the width of the semiconductor sleeve is between about 3 nm and 80 nm. It will be understood by a skilled artisan that the width of the semiconductor sleeve 460 can be similar to the lateral extension of the cap 430 beyond the TSV 408 over which the cap 430 is disposed. Beneficially, the semiconductor sleeve 460 provides additional protection to the TSV 408 and the TSV liner 410, from the etchant used to etch the bulk semiconductor portion 402, and can also mechanically reinforce the TSV 408 and its liner 410 during subsequent planarization. To form the sleeve 460, the bulk semiconductor portion 402 is directionally etched from the back side 406 (e.g., by a reactive ion etch or by a plasma etch). In some embodiments, as a result of the directional etch, the semiconductor sleeve 460 has a retrograde angle, such that the sleeve 460 is wider near the back surface of the TSV 408 and thinner toward the front side 404 of the TSV 408.

FIG. 4D shows the structure of FIG. 4C after the overcoated selective caps have been removed and a dielectric layer 422 has been disposed over the back side 406. The selective caps can be selectively removed, for example, during the CMP process. In other arrangements, the caps 430 can remain over the TSVs 408 and the dielectric layer 422 is formed over the caps 430, similar to the process of FIG. 3F. The deposition of the dielectric layer 422 shown in FIG. 4D is similar to the deposition of the dielectric layer 322 shown in FIG. 3F.

FIG. 4E illustrates a microelectronic structure 400, formed after the back side 406 of the structure shown in FIG. 4D is planarized to reveal the TSVs 408. This planarization is similar to the planarization illustrated in FIG. 3G and can leave the back side 406 sufficiently smooth for hybrid bonding.

The microelectronic structure 400 shown in FIG. 4E is analogous to the microelectronic structure 300 shown in FIG. 3G, but the microelectronic structure 400 of FIG. 4E includes the semiconductor sleeves 460 disposed between the TSV liners 410 and the dielectric layer 422. The TSVs 408 and the TSV liners 410 are separated from the dielectric layer 422 by the material of the bulk semiconductor portion 402. Accordingly, the sleeves 460 form semiconductor regions on the back surface of the microelectronic structure 400 that separate the conductive regions on the back surface of the microelectronic structure 400 from the dielectric regions on the back surface of the microelectronic structure 400.

FIG. 4F shows a multi-component bonded structure 450 comprising a microelectronic structure 400 (like the one shown in FIG. 4E) hybrid bonded to additional substrates 454. The illustrated bonded structure 450 has three tiers of microelectronic structures 400 and additional substrates 454, which are also shown to have the TSV 408, sleeve 460, and dielectric layer 422 backside structures of the microelectronic structure 400. The bottom tier of the illustrated arrangement is an unsingulated substrate (e.g., a wafer) with many TSVs 408. The second tier shows a plurality of singulated dies hybrid bonded to the bottom tier in front-to-back configurations. The top tier shows one singulated microelectronic structure 400 hybrid bonded to one of the dies of the second tier in a front-to-back configuration. Each component has a plurality of TSVs 408, and each illustrated TSV 408 has a semiconductor sleeve 460 separating the TSV 408 from a dielectric layer 422, which can serve as a hybrid bonding layer. The hybrid bonding surface includes both nonconductive surfaces (e.g., from the dielectric layer 422) and conductive surfaces (e.g., from TSVs 408 or any overlying contact pads). In some embodiments, it may be preferable that the width of the conductive elements, such as pads, via, and/or traces, at the bonding surface of the dies 400 or 452 be smaller than the corresponding conductive elements having the semiconductor sleeve 460.

FIGS. 5A-5F schematically present a method of processing the back side 506 of a substrate to form a microelectronic structure 500, in accordance with a third embodiment. In this method, a back side 506 of a bulk semiconductor portion 502 can be thinned to expose embedded TSVs 508 and prepared for hybrid bonding, using backside caps 430, at least portions of which can remain in the device, which leads to the formation of a semiconductor sleeve 560 and multiple conductors in the TSV structure.

FIG. 5A is analogous to FIG. 4A, insofar as they both illustrate thinned, decontaminated bulk semiconductor portions (e.g., 502) before selective caps (e.g., 530) are deposited on the back side (e.g., 506) of the revealed TSVs (e.g., 508). However, unlike in FIG. 4A, the TSVs 508 shown in FIG. 5A are recessed relative to the bulk semiconductor portions 502 before providing the selective caps 530. The TSVs 508 can be selectively recessed or etched, such as by selective metal or selective copper etching, for example, using a very to dilute acid. In some embodiments, the etching formulation may comprise very dilute acid containing less 0.5% hydrogen peroxide. The choice of the acid is such that the formulated chemistry will selectively etch the desired amount of the conductive TSV portion to form the desired recess. In some embodiments, the top surface of the TSV 508 may be oxidized by wet etch or by plasma methods, and the resulting oxide stripped with a dilute acid. Depending upon the materials of the TSV liners 510 and the etch chemistry, the TSV liners 510 can also be recessed, or can remain lining the resulting recesses 532. The depths of the recesses 532 into the back side 506 of the bulk semiconductor portion 502 may vary. In some embodiments, the depths of the recesses 532 into the back sides 506 of the TSVs 508 can be in a range of approximately 10 nm to 10 microns, or 20 nm to 1 micron, or 25 nm to 500 nm, or 5 nm to 80nm.

FIG. 5B is analogous to FIG. 4B, insofar as they both illustrate the selective formation of overcoated (mushroomed) selective caps (e.g., 530) on the back side (e.g., 506) of the TSVs (e.g., 508). In both embodiments, the selective caps (e.g., 530) comprise a metal (e.g., NiP or CoP) and are given enough time during the deposition reaction to mushroom, or to grow both vertically and laterally to cover or shadow a part of the back surface of the bulk semiconductor portion 502 adjacent to the TSVs 508. One difference between FIGS. 5B and 4B is that the TSVs 508 of FIG. 5B have recesses 532 relative to the bulk semiconductor portion 502. Because of this, the caps 530 shown in FIG. 5B selectively fill in the TSV recesses 532, forming embedded cap portions 534 below the mushroomed overcoatings of the selective caps. Each selective cap 530 includes both the embedded cap portion 534 and the mushroomed overcoating.

FIG. 5C is analogous to FIG. 4C: they both illustrate the structure from the preceding figure after a directional etch that leaves the TSVs (e.g., 508) surrounded by semiconductor sleeves (e.g., 560).

FIG. 5D is analogous to FIG. 4D: they both illustrate the structure from the preceding figure, after a dielectric layer (e.g., 522) is deposited over the back side (e.g., 506) of the structure to fill in the directionally etched bulk semiconductor portion (e.g., 502). Before the dielectric layer (e.g., 522) is deposited over the back side (e.g., 506) of the structures illustrated in each of FIGS. 5D and 4D, the part of the selective cap 530 extending above the semiconductor sleeve 560 (e.g., the mushroomed overcoating) and any remaining TSV liner 510 within the sleeve 560 is removed, such as by a timed selective etch. Such an etch may also clean any metal from the semiconductor surface than may have been sputtered from the exposed metallic cap portions 534 during the preceding semiconductor recessing process (e.g., SF6 REI). However, whereas in FIG. 4D this meant substantially the entire cap 460 was removed from each TSV 408, in FIG. 5D this means at least portions of the embedded cap portion 534 remain in the resulting structure substantially covering the remainder of the TSV 408 (e.g., copper). In the illustrated structure, the remaining portion of each selective cap 530 is part of or all of the embedded cap portion 534. In the illustrated embodiment, this embedded cap portion 534 remains as a permanent feature of microelectronic structures 500 (FIG. 5E) formed according to this method. In some embodiments, one or more dielectric layers 522 may be coated over the structure of FIG. 5C. In some embodiments, the coated layer may comprise a planarizing or non-planarizing dielectric material, for example, a polymeric material. In some embodiments, the back side 506 of the substrate is planarized to form the structure of FIG. 5E.

FIG. 5E is analogous to FIG. 4E: they both illustrate microelectronic structures (e.g., 500) resulting from the planarization of the back side (e.g., 506) of the structure shown in the preceding figure until the dielectric layer (e.g., 522) is no longer covering the back side (e.g., 506) of the TSVs (e.g., 508). However, whereas in FIG. 4E the planarization revealed the TSVs 408 at the back side 406, in FIG. 5E the planarization reveals the embedded cap portions 534 of the selective caps 530 at the back side 506. The microelectronic structure 500 of FIG. 5E has a final thickness 514 and comprises TSVs 508 that have two parts: a tip portion and a second via portion. The tip portion can be at the back side of the substrate, and the second via portion can be at the front side of the substrate. The tip portion can comprise a first conductive material. The second via portion can comprise a second conductive material different from the first conductive material. The tip portion is at the back side 506 of each TSV 508 and is the remaining part of the embedded cap portion 534, which can comprise, for example, NiP or CoP or combinations of such selectively deposited conductive materials. The second via portion is the remainder of the originally-formed TSV 508, as shown in FIG. 5A, which can comprise copper. In some embodiments, the embedded cap portion 534 can have a thickness of approximately 10 nm to 10 microns, 20 nm to 1 micron, 25 nm to 500 nm, or 3 nm to 70 nm. In some embodiments, the embedded cap portions 534 improve the electromigration resistance of the metal of the TSV by suppressing the surface mobility of copper atoms at the copper-cap interface.

FIG. 5F is analogous to FIG. 3H: they both illustrate forming an RDL structure (e.g., 540) or other hybrid bonding layer on the back surface of the microelectronic structure (e.g., 500) of the preceding figure. While the RDL structure 540 in FIG. 5F can be omitted, the conductive portions 542 of the RDL structure 540 can comprise copper at the new back surface of the structure, which can be more easily bonded than the material of the embedded cap portion 534, e.g., NiP or CoP.

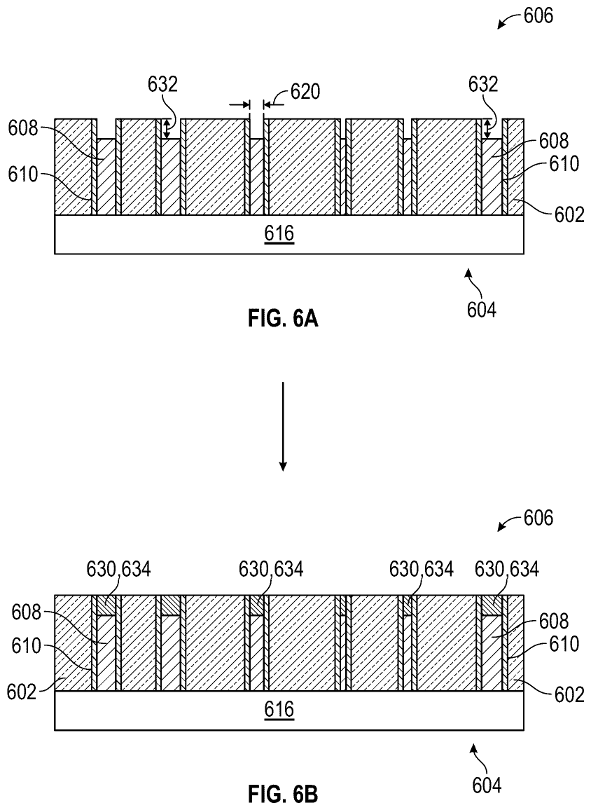

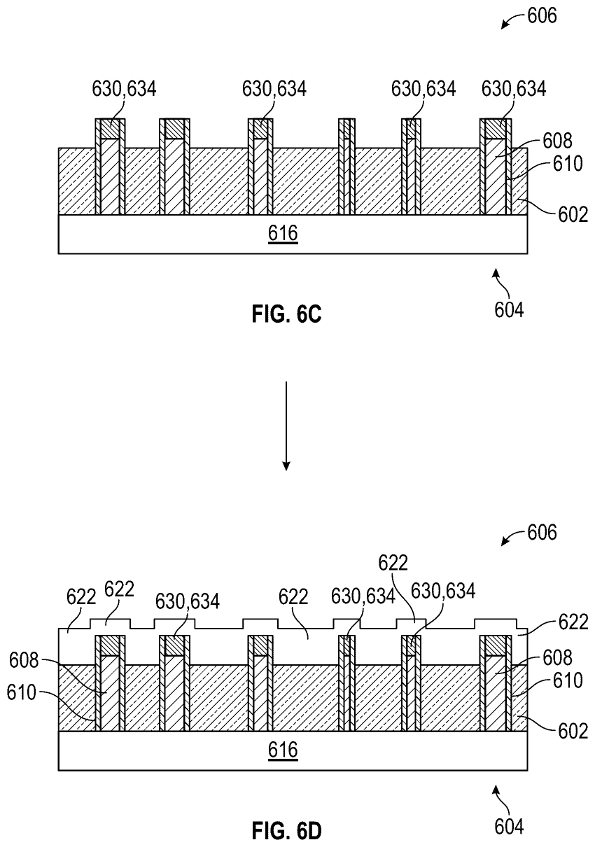

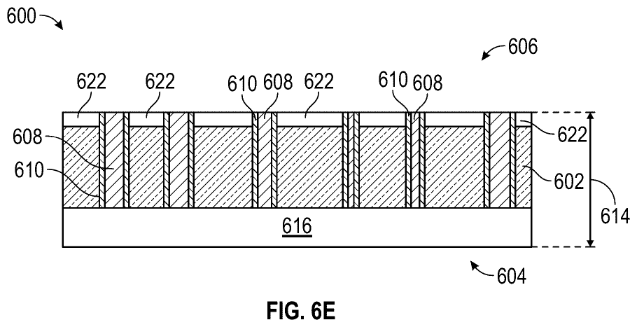

FIGS. 6A-6E schematically present a method of processing the back side 606 of a substrate to form a microelectronic structure 600, in accordance with a fourth embodiment. In this method, a backside 606 of a bulk semiconductor portion 602 can be thinned to expose embedded TSVs 608 and prepared for hybrid bonding, using selective backside caps 620. FIG. 6A is similar to FIG. 5A, depicting the structure after recessing TSVs 608 below the planarized backside of the semiconductor portion 602.

FIG. 6B is analogous to FIG. 5B, but the selective caps 630 of FIG. 6B are not overcoated. In other words, while both figures include an embedded capping layer (e.g., 634), unlike the selective caps 530 illustrated in FIG. 5B, the selective caps 630 illustrated in FIG. 6B substantially cover the back sides 606 of each TSV 608 and do not significantly encroach over the bulk semiconductor portions 602 adjacent to the TSVs 608 on the back side 606. In other words, whereas the selective caps 530 of FIG. 5B comprise both embedded cap portions 534 and a mushroomed overcoat, the selective caps 630 of FIG. 6B predominantly or exclusively comprise embedded cap portions 634 but not a mushroomed overcoat. Another difference between the selective caps 630 of FIG. 6B and those of FIG. 5B: the selective caps 630 of FIG. 6B can be formed by a self-limiting deposition process, for example the process for forming BTA as described above. However, if the selective caps 630 of FIG. 6B are formed by a non-self-limiting process, such as electroless Ni, Co, Sn, Ag, Pd, and/or In deposition processes, the process of depositing the selective caps 630 can be stopped before any significant lateral overgrowth.

FIG. 6C is similar to FIG. 3E. They both illustrate etching back the bulk semiconductor portion (e.g., 602) to form protruding TSVs (e.g., 608) that can protrude above bulk semiconductor portion (e.g., 602) by, for example, approximately 1,000 nm. Depending upon whether the selective caps 630 are metallic, the semiconductor surface may be cleaned and decontaminated at this stage of any metal that may have been sputtered from the exposed metallic cap portions 634 during the preceding semiconductor recessing process (e.g., SF6 RIE).

FIG. 6D is similar to FIG. 3F. They both illustrate the structure from the preceding figure, after a dielectric layer (e.g., 622) is deposited over the back side (e.g., 606) of the structure to fill in the etched bulk semiconductor portion 602.

FIG. 6E is analogous to FIG. 5E: they both illustrate microelectronic structures (e.g., 600) resulting from the planarization of the back side (e.g., 606) of the structure shown in the preceding figure until the embedded cap portions (e.g., 634) are revealed or removed, similar to FIG. 3G. If the cap portions 634 are conductive (e.g., alloyed regions of the TSV), they can remain in the final structure, similar to FIGS. 5E and 5F, and can interdiffuse with conductive pads of opposing substrates to which they are bonded, such that the alloying elements may be distributed between the bonded conductive structures. Like the embodiment of FIG. 3G, but unlike the embodiments of FIGS. 4E and 5E, the microelectronic structure 600 of FIG. 6E does not have semiconductor sleeves separating the TSV liners 610 from the dielectric layer 622. The process may subsequently treat the back side 606 surface of the microelectronic structure 600 for hybrid bonding (sufficiently low roughness, possible activation and/or termination), or RDL structures can be added and treated for hybrid bonding as described for prior embodiments.

FIGS. 7A-7F schematically present a method of processing the back side 706 of a substrate to form a microelectronic structure 700, in accordance with a fifth embodiment. In this method, a back side 706 of a bulk semiconductor portion 702 can be thinned to expose embedded TSVs 708 and prepared for hybrid bonding, using patterned backside caps 730. The method shown in FIGS. 7A-7F is analogous to the method shown in FIGS. 4A-4E, but the protective caps 430 shown in FIGS. 4B and 4C are selective caps 430, while the protective caps 730 shown in FIGS. 7B and 7C are patterned caps 730. FIG. 7A is similar to FIG. 4A.

FIG. 7B is analogous to FIG. 4B, insofar as they both illustrate protective caps (e.g., 730) on the back side (e.g., 706) of the TSVs (e.g., 708) that also cover adjacent portions of the bulk semiconductor portions (e.g., 702) on the back side (e.g., 706). However, the protective caps 430 illustrated in FIG. 4B are selective caps 430, while the protective caps 730 illustrated in FIG. 7B are patterned caps 730. In some arrangements, the patterned protective caps 730 illustrated in FIG. 7B can comprise resist itself or hard mask materials patterned by overlying resist. If a hard mask, the protective caps 730 can be dielectric (in which case they will be removed as shown in FIG. 7D) or can be conductive (in which they can be removed as shown or can remain in the final product as a contact pad of the TSVs 708). In the illustrated embodiment, the patterned caps 730 are wider than the TSVs 708 they cover, but this is not necessarily the case. In some embodiments (not shown), the patterned caps cover the TSVs but are not substantially wider than the TSVs. In some other embodiments (also not shown), one or more but not all of the patterned caps are wider than the TSVs they cover but the remaining patterned caps are not.

FIG. 7C is analogous to FIG. 4C: the bulk semiconductor portion (e.g., 702) of the structure illustrated in the preceding figure is directionally etched from the back side (e.g., 706), and semiconductor sleeves (e.g., 760) are formed in the etching shadow of the protective caps (e.g., 730). In some embodiments (not shown) in which a patterned cap covers the TSV without being substantially wider than the TSV, a semiconductor sleeve will not be formed around the TSV.

FIG. 7D illustrates removing the patterned caps 730 from the back side 706 of the TSVs 708 and from the rest of the back side 706 of the substrate. In some embodiments, this is accomplished by stripping resist and cleaning the back side 706 of the substrate. In other embodiments, a hard mask material can be etched selectively relative to the exposed semiconductor and underlying TSV materials. In still other embodiments, conductive patterned caps can be left in place and serve as contact pads over the TSVs.

FIG. 7E is analogous to FIG. 4D: they both illustrate the deposition of a dielectric layer (e.g., 722) over the back side (e.g., 722) of the bulk semiconductor portion (e.g., 702), semiconductor sleeves (e.g., 760), and TSVs (e.g., 708). Moreover, in both Figures, the dielectric layer (e.g., 722) fills in the previously etched out parts of the bulk semiconductor portion (e.g., 702).

FIG. 7F is similar to FIG. 4E: they both illustrate microelectronic structures (e.g., 700) resulting from the planarization of the back side (e.g., 706) of the structure shown in the preceding figure until the TSVs (e.g., 708) are revealed. Indeed, as mentioned above, the microelectronic structure of FIG. 7F is similar to that of FIG. 4E; they differ primarily in method of manufacture. The process may subsequently treat the back side 706 surface of the microelectronic structure 700 for hybrid bonding (sufficiently low roughness, possible activation and/or termination), or RDL can be added and treated for hybrid bonding as described for prior embodiments.

In one aspect, a microelectronic structure includes a bulk semiconductor portion having a front surface and a back surface opposite the front surface. A plurality of conductive via structures extend at least partially through the bulk semiconductor portion. A dielectric portion at least partially overlie the back surface of the bulk semiconductor portion. A back surface of the microelectronic structure includes dielectric regions including the dielectric portion, and conductive regions including the plurality of conductive via structures. The conductive via structures are separated from the dielectric portion by the bulk semiconductor portion.

In some embodiments, the back surface of the microelectronic structure is prepared for hybrid bonding. In some embodiments, the bulk semiconductor portion separating the conductive via structures from the dielectric portion is a semiconductor sleeve with a substantially annular cross-section. In some embodiments, the semiconductor sleeve has a retrograde angle, such that the sleeve is wider near the back surface of the microelectronic structure and thinner toward a front side of the microelectronic structure. In some embodiments, the width of the semiconductor sleeve is about 3 nm to 70 nm. In some embodiments, the thickness of the dielectric portion is at least about 50 nm. In some embodiments, the microelectronic structure further includes a via liner between each conductive via structure and the bulk semiconductor portion. In some embodiments, the via liners lack stress cracking. In some embodiments, the conductive via structures include a tip portion at the back side of the microelectronic structure including a first conductive material and a second via portion at the front side of the microelectronic structure including a second conductive material different from the first conductive material. In some embodiments, the second via portion includes copper. In some embodiments, the tip portion at least one selected from the group consisting of NiP or CoP. In some embodiments, the tip portion has a thickness of between about 20 nm and 1 micron. In some embodiments, a bonded structure includes a microelectronic structure and a second substrate directly bonded to the microelectronic structure.

In another aspect, a method of forming a microelectronic structure includes providing a bulk semiconductor with a front surface and a back surface opposite the front surface. The method also includes providing a plurality of conductive vias at least partially embedded in the bulk semiconductor. The method also includes revealing the plurality of conductive vias from the back surface. The method also includes forming a protective cap on each of the conductive vias on the back surface of the bulk semiconductor. The method also includes etching the back surface of the bulk semiconductor while the protective caps cover the conductive vias to form protruding conductive vias. The method also includes depositing a dielectric layer over the back surface of the bulk semiconductor and over the protruding conductive vias. The method also includes planarizing the dielectric layer to reveal the plurality of conductive vias from the back surface.

In some embodiments, the conductive vias vary from one another in width and depth when they are provided. In some embodiments, the protective cap is removed. In some embodiments, forming a protective cap includes patterning a protective cap. In some embodiments, the protective cap includes photoresist. In some embodiments, forming a protective cap includes selectively forming a protective cap. In some embodiments, the protective cap includes one selected from the group consisting of NiP, CoP, and BTA. In some embodiments, when forming protective caps, the protective caps substantially cover a back side of each conductive via, substantially without encroaching over bulk semiconductor. In some embodiments, when forming protective caps, the protective caps substantially cover a back side of each conductive via and extend laterally to cover a portion of the bulk semiconductor around each conductive via. In some embodiments, the microelectronic structure includes a semiconductor sleeve separating each conductive via from the dielectric layer. In some embodiments, revealing the plurality of conductive vias includes chemical mechanical planarization. In some embodiments, the method further includes after revealing the conductive vias and before forming protective caps, selectively recessing the conductive vias. In some embodiments, forming protective caps includes filling the selectively recessed portions of the conductive vias. In some embodiments, the method further includes, after revealing the conductive vias and before selectively forming protective caps, decontaminating the bulk semiconductor of any material from conductive vias that may have contaminated the bulk semiconductor while revealing the conductive vias. In some embodiments, a method of forming a bonded structure includes providing a microelectronic structure and direct bonding the microelectronic structure to a second substrate.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A microelectronic structure comprising:
a bulk semiconductor portion having a front surface and a back surface opposite the front surface;
a plurality of conductive via structures extending at least partially through the bulk semiconductor portion; and
a dielectric portion at least partially overlying the back surface of the bulk semiconductor portion,
wherein a back surface of the microelectronic structure comprises dielectric regions including the dielectric portion, and conductive regions including the plurality of conductive via structures, and
wherein the conductive via structures are separated from the dielectric portion by the bulk semiconductor portion.

2. The microelectronic structure of claim 1, wherein the back surface of the microelectronic structure is prepared for hybrid bonding.

3. The microelectronic structure of claim 1, wherein the bulk semiconductor portion separating the plurality of conductive via structures from the dielectric portion is a semiconductor sleeve with a substantially annular cross-section.

4. The microelectronic structure of claim 3, wherein the semiconductor sleeve has a retrograde angle, such that the sleeve is wider near the back surface of the microelectronic structure and thinner toward a front side of the microelectronic structure.

5. The microelectronic structure of claim 3, wherein a width of the semiconductor sleeve is about 3 nm to 70 nm.

6. The microelectronic structure of claim 1, wherein a thickness of the dielectric portion is at least about 50 nm.

7. The microelectronic structure of claim 1, further comprising a via liner between each of the plurality of conductive via structures and the bulk semiconductor portion.

8. The microelectronic structure of claim 5, wherein the via liners lack stress cracking.

9. The microelectronic structure of claim 1, wherein the plurality of conductive via structures comprise a tip portion at the back surface of the microelectronic structure comprising a first conductive material and a second via portion at the front side of the microelectronic structure comprising a second conductive material different from the first conductive material.

10. The microelectronic structure of claim 9, wherein the second via portion comprises copper.

11. The microelectronic structure of claim 9, wherein the tip portion is selected from the group consisting of NiP and CoP.

12. The microelectronic structure of claim 9, wherein the tip portion has a thickness of between about 20 nm and 1 micron.

13. A bonded structure comprising:
a microelectronic structure of claim 1, and
a second substrate directly bonded to the microelectronic structure.

14. A method of forming a microelectronic structure, the method comprising:
providing a bulk semiconductor with a front surface and a back surface opposite the front surface;
providing a plurality of conductive vias at least partially embedded in the bulk semiconductor;
revealing the plurality of conductive vias from the back surface of the bulk semiconductor;
forming a protective cap on each of the plurality of conductive vias on the back surface of the bulk semiconductor;
etching the back surface of the bulk semiconductor while the protective caps on each of the plurality of conductive vias cover each of the conductive vias to form protruding conductive vias;
depositing a dielectric layer over the back surface of the bulk semiconductor and over the protruding conductive vias; and
planarizing the dielectric layer to reveal the plurality of conductive vias from the back surface.

15. The method of claim 14, wherein the plurality of conductive vias vary from one another in width and depth when the plurality of conductive vias are provided.

16. The method of claim 14, wherein the protective cap on each of the plurality of conductive vias is removed.

17. The method of claim 16, wherein forming the protective cap on each of the plurality of conductive vias comprises patterning the protective cap on each of the plurality of conductive vias.

18. The method of claim 17, wherein the protective cap on each of the plurality of conductive vias comprises photoresist.

19. The method of claim 14, wherein forming the protective cap on each of the plurality of conductive vias comprises selectively forming the protective cap on each of the plurality of conductive vias.

20. The method of claim 14, wherein the protective cap on each of the plurality of conductive vias comprises a protective cap selected from the group consisting of NiP, CoP, and BTA.

21. The method of claim 14, wherein, when forming the protective cap on each of the plurality of conductive vias, the protective cap substantially covers a back side of each conductive via, substantially without encroaching over the bulk semiconductor.

22. The method of claim 14, wherein, when forming the protective cap on each of the plurality of conductive vias, the protective cap substantially covers a back side of each conductive via and extend laterally to cover a portion of the bulk semiconductor around each conductive via.

23. The method of claim 21, wherein the microelectronic structure comprises a semiconductor sleeve separating each of the plurality of conductive vias from the dielectric layer.

24. The method of claim 14, wherein revealing the plurality of conductive vias comprises chemical mechanical planarization.

25. The method of claim 14, further comprising, after revealing the plurality of conductive vias and before forming the protective cap on each of the plurality of conductive vias, selectively recessing the plurality of conductive vias.

26. The method of claim 25, wherein forming the protective cap on each of the plurality of conductive vias comprises filling the selectively recessed portions of the plurality of conductive vias.

27. The method of claim 14, further comprising, after revealing the plurality of conductive vias and before selectively forming the protective cap on each of the plurality of conductive vias, decontaminating the bulk semiconductor of any material from the plurality of conductive vias that may have contaminated the bulk semiconductor while revealing the plurality of conductive vias.

28. A method of forming a bonded structure comprising:
providing the microelectronic structure formed by the method of claim 14, and direct bonding the microelectronic structure to a second substrate.
